(19) United States
(12) Patent Application Publication
(10) Pub. No.: US 2025/0122618 A1
(43) Pub. Date: Apr. 17, 2025

(54) PLASMA SOURCE AND APPARATUS FOR ATOMIC LAYER DEPOSITION

(71) Applicant: SparkNano B.V., Eindhoven (NL)

(72) Inventors: Paul POODT, Deest (NL); Jeroen Antonius SMELTINK, Mierlo (NL); Cornelis Henrikus FRIJTERS, Eindhoven (NL); Viktor TIELEN, Eindhoven (NL)

(21) Appl. No.: 18/870,537

(22) PCT Filed: Jun. 1, 2023
(86) PCT No.: PCT/NL2023/050308

§ 371 Date: Nov. 29, 2024

(30) Foreign Application Priority Data
Jun. 2, 2022 (NL) 2032061

(51) Int. Cl. C23C 16/455; H01J 37/32

(52) U.S. Cl. CPC C23C 16/45544; C23C 16/45595; H01J 37/32449; H01J 2237/3321

(57) ABSTRACT

A plasma source comprising a plasma deposition head, an electrode plate, and a gas supply system. The plasma deposition head comprises an aperture for delivering atmospheric plasma to a substrate, and a slotted cavity extending from the aperture. The electrode plate is mounted in the slotted cavity and extends from an interior of the deposition head towards the aperture. The gas supply system comprises a gas inlet, a gas supply chamber and gas outlets. The gas supply chamber is arranged for receiving a mass flow of gas from the gas inlet and dividing the mass flow of gas between the gas outlets. The gas outlets are provided on opposing sides of the electrode plate. In use, the mass flow of gas is divided for providing a flow of atmospheric plasma on the opposing sides of the electrode plate.

The invention relates to a plasma source, and to an apparatus for atomic layer deposition comprising such a plasma source.

Spatial Atomic layer deposition (S-ALD) is a thin film growth technique based on the sequential exposure of a substrate to half-reactions. In plasma enhanced ALD one the half reactions is formed by plasma species.

To improve the plasma source efficiency it is beneficial to have a uniform mass flow of gas towards the substrate. In a plasma source gas is supplied through a narrow gap along a high voltage electrode. The gap is typically defined by the distance between one side of the high voltage electrode and an opposing wall of a second electrode, with the gap width e.g. set in a range between 0.05 and 0.25 mm. Due to manufacturing and/or alignment tolerances of the electrode, which is typically a ceramic plate which has a buried conductor in it substantially over its entire plate surface, the gap width may vary along the length of the gap, due to a deviation in the planarity of the electrode plate, in the direction of the mass flow of gas which may negatively affect the deposition quality. These variations, in turn, create areas of higher and lower flow resistance along the gap length, which causes variations in the mass flow of gas towards the substrate.

The uniformity of the mass flow of gas towards the substrate is strongly dependent on the gap width variation. By accurately defining the geometrical properties of the gap and the high voltage electrode during the manufacturing and assembly process, the gap width variation can be reduced. However, variations inherent to the manufacturing process, such as flatness and straightness tolerances, may leave some geometrical errors, which can still be a limiting factor for the efficiency of the plasma source.

Moreover, during operation of the plasma source, plasma generated inside the gap creates a high temperature environment. Thermal gradients and heterogenous thermal expansion of components or structures of the plasma source may lead to relative displacements and misalignments of parts. As such, thermal effects may additionally vary the geometrical properties of the gap, and thus its resistance to the flow of gas, during use of the plasma source, thereby potentially further limiting its efficiency.

It is an object of the present invention to provide a plasma source, e.g. for atomic layer deposition, with an improved uniformity of mass flow of gas towards a substrate.

### SUMMARY

In summary, the invention pertains to a plasma source. The plasma source comprises a plasma deposition head, an electrode plate, and a gas supply system. The plasma deposition head comprises an aperture for delivering an atmospheric plasma from the deposition head to a substrate, and comprises a slotted cavity having parallel walls extending from opposing edges of the aperture. The electrode plate is mounted in the slotted cavity and extends from an interior of the deposition head towards the aperture. The gas supply system comprises a gas inlet, a gas supply chamber and gas outlets. The gas supply chamber is arranged for receiving a mass flow of gas from the gas inlet and dividing the mass flow of gas between the gas outlets.

The gas outlets are provided on opposing sides of the electrode plate, and, in use, the mass flow of gas is equally divided for providing a flow of atmospheric plasma on the opposing sides of the electrode plate.

By dividing the mass flow of gas in the slotted cavity between the opposing sides of the electrode plate, the nominal gap width as well as the geometrical variations of the gap width along the length of the gap, e.g. caused by flatness errors of the electrode plate, are reduced. As a result, the uniformity of the mass flow of gas through the gaps on each opposing side of the electrode plate is significantly improved, compared to a conventional approach in which a single mass flow is passed though a single gap.

For example, planarity errors of the electrode plate may create an increased flow resistance on one side of the electrode plate, yet simultaneously create a decreased flow resistance on the opposing side of the electrode plate. As such, differences in flow resistance along the slotted cavity on one side of the electrode plate can be compensated for by counteracting differences in flow resistance along the slotted cavity on the other side of the electrode plate. In contrast to conventional plasma sources with a single mass flow of gas, having divided flows of atmospheric plasma provided from opposing sides of the electrode plate provides a net combined flow of atmospheric plasma with a more uniform mass flow, effectively compensating for each other.

To deliver atmospheric plasma along a certain width of a substrate, the mass flow of gas may be divided uniformly along the width of the plasma source. In such cases, the gas supply chamber preferably extends along a width of the electrode plate and across the opposing sides of the electrode plate. Accordingly, the mass flow of gas is fed to a large volume that is provided before the slotted cavity along the width of the electrode plate, and the slotted cavity can function as a flow restriction, such that the mass flow of gas is uniformly distributed along the width of the electrode plate.

In some embodiments, the gas supply chamber and the gas outlets are integrated in the plasma deposition head. In this way, volumes and channels defining the flow characteristics of the gas can be controlled during manufacturing of the plasma deposition head, thereby reducing manufacturing and assembly tolerances of the plasma source.

To split up functions, the gas supply chamber can comprise a divide volume and a supply volume. The divide volume may be connected to the gas inlet and may extend across the opposing sides of the electrode plate, wherein the divide volume is arranged for receiving the mass flow of gas from the gas inlet, and dividing the mass flow of gas between the opposing sides of the electrode plate. The supply volume may be connected to the divide volume and may extend along a width of the electrode plate, wherein the supply volume is arranged for receiving the divided mass flow of gas from the divide volume, and uniformly supplying the mass flow of gas along the width of the electrode plate towards the gas outlets.

The gas supply system may further comprise a channelled section, comprising a plurality of channels arranged along the width of the electrode plate and connecting the gas supply chamber to respective gas outlets. Each channel of the plurality of channels can be arranged for directing a portion of the mass flow of gas from the gas supply chamber towards a respective gas outlet. In this way, the mass flow of gas along the width of the electrode plate can be controlled, e.g. to uniformly divide the mass flow of gas along the width of the electrode. For example, by individually adjusting one or more specific portions of the mass flow of gas through the plurality of channels, a non-uniform mass flow of gas along the width of the electrode plate can be corrected.

In some embodiments, the channelled section is provided by a stack of shim plates, mounted between the slotted cavity wall and the electrode plate. The stack of shim plates may cover the gas supply chamber and the gas outlets, and the plurality of channels can be provided by cut outs in each shim plate of the stack of shim plates. By using shim plates, the channelled section is highly configurable, e.g. by changing the size and shape of the cut outs, the number of shim plates in a stack, or the thickness of shim plates. Accordingly, different configurations of the channelled section can be created by using different combinations of shim plates, which can be manufactured and assembled with high precision, thereby allowing to reliably determine the flow characteristics of the plasma source.

To determine the mass flow of gas from the gas supply chamber towards the gas outlets along the width of the electrode plate, the channelled section can comprise restrictions. The restrictions can for example be provided in the plurality of channels, e.g. to create an increased flow resistance acting on portions of the mass flow of gas directed through one or more channels of the plurality of channels.

The restrictions can for example be formed by decreasing a size of one or more cut outs in the shim plates.

Alternatively, or additionally, the restrictions can be formed by decreasing a thickness of one or more shim plates.

In some further embodiments, the gas supply system comprises a flow homogenizer, disposed between the channelled section and the gas outlets, and arranged for equally distributing the mass flow of gas along the width of the electrode plate. The flow homogenizer may comprise holes that extend from the plurality of channels into the wall at an acute angle and connect with a recess in the wall that is in communication with the slotted cavity. The recess may comprise a homogenizer plane that is oriented substantially perpendicular to the mass flow of gas directed through the holes. By the mass flow of gas hitting the homogenizer plane, it is spread out across the homogenizer plane and guided into the slotted cavity. Accordingly, the mass flow of gas is divided more uniformly by passing through the flow homogenizer.

In some preferred embodiments, the plasma deposition head comprises a first part that defines a first wall of the slotted cavity, and a second part that defines a second wall of the slotted cavity. The electrode plate may comprise a mountable part that is mounted to the first and/or second part of the plasma deposition head, and a suspendable part that extends from the mountable part and is free on all other sides. In this way, the mass flow of gas passing along the slotted cavity walls and the electrode plate can be well-defined with relatively high precision, since the above described architecture substantially separates the geometrical features of the slotted cavity and the electrode plate into planar surfaces which are easily accessible by manufacturing tools.

The mountable part of the electrode plate can for example be clamped between the first and second part of the plasma deposition head.

In some variants of these embodiments, a stack of shim plates may be clamped between the first or second part and the electrode plate on each opposing side of the electrode plate. The stack of shim plates may cover the gas supply chamber and the gas outlets. Each shim plate of the stack of shim plates can be provided with cut outs, thereby creating a channel structure, for directing the mass flow of gas from the gas supply chamber through the stack of shim plates towards the gas outlets.

Preferably, each stack of shim plates has a total thickness that defines a respective nominal gap width between the first and second walls of the slotted cavity and the opposing sides of the electrode plate. Accordingly, the nominal gap width, and hence the gap width variation, is determined by the thickness of the shim plates, which can for example be controlled by measurement and selection.

In some embodiments, the plasma deposition head comprises an exhaust system for discharging gas from the substrate, comprising an exhaust port and exhaust channels integrated in the plasma deposition head, wherein the exhaust channels extend between the substrate and the exhaust port parallel to the slotted cavity on each opposing side of the electrode plate. Accordingly, after atmospheric plasma has interacted with the substrate, the gas can be discharged through the exhaust channels on either side of the electrode plate, to limit constraining the mass flow of gas along the opposing sides of the electrode plate.

Preferably, the electrode plate comprises a distal edge that is aligned with the opposing edges of the aperture within 3 millimeters. In this way, the flows of atmospheric plasma provided on the opposing sides of the electrode plate substantially remains on each opposing side of the electrode plate, until they are delivered through the aperture of the plasma deposition head to interact with the substrate. As such, geometrical variations in the final section of the slotted cavity, between the distal edge of the electrode plate and the opposing edges of the aperture, have a limited effect on the mass flow of gas.

Preferably, the electrode plate comprises laminated alumina layers, and a metal electrode is printed on one of the alumina layers. While in this manufacturing technique the flatness of the electrode plate may be limited, the present invention allows using these types of electrode plate in a plasma source regardless of geometrical variations along the electrode plate, by having differences in flow resistance along the slotted cavity on one side of the electrode plate compensate for differences in flow resistance along the slotted cavity on the other side of the electrode plate.

The plasma deposition head can for example be made of an electrically conductive material, such as a metal. In this way, the plasma deposition head, specifically the walls of the slotted cavity can form a counter electrode to the plate electrode, for generating an atmospheric plasma in the slotted cavity.

Other aspects of the invention pertain to an apparatus for atomic layer deposition, comprising a plasma source as described herein. The apparatus may further comprise a transport mechanism arranged for transporting a substrate and the plasma source relative to each other in parallel to a plane of the substrate. In this way, atmospheric plasma delivered from the plasma source can interact with a substrate area as it is transported parallel to the plane of the substrate.

### BRIEF DESCRIPTION OF THE DRAWINGS

The invention will be further elucidated in the figures:

FIG. 1 provides a schematic representation of an embodiment of a plasma source;

FIG. 2 illustrates a section view of another or further embodiment of the plasma source;

FIG. 3 provides an exploded view of another or further embodiment of the plasma source;

FIG. 4 provides a section view of the embodiment of FIG. 3 in unexploded condition;

FIG. 5 illustrates an apparatus for atomic layer deposition comprising a plasma source as described herein.

### DETAILED DESCRIPTION

The invention is described more fully hereinafter with reference to the accompanying drawings, in which embodiments of the invention are shown. In the drawings, the absolute and relative sizes of systems, components, layers, and regions may be exaggerated for clarity. Embodiments may be described with reference to schematic and/or cross-section illustrations of possibly idealized embodiments and intermediate structures of the invention. In the description and drawings, like numbers refer to like elements throughout. Relative terms as well as derivatives thereof should be construed to refer to the orientation as then described or as shown in the drawing under discussion. These relative terms are for convenience of description and do not require that the system be constructed or operated in a particular orientation unless stated otherwise.

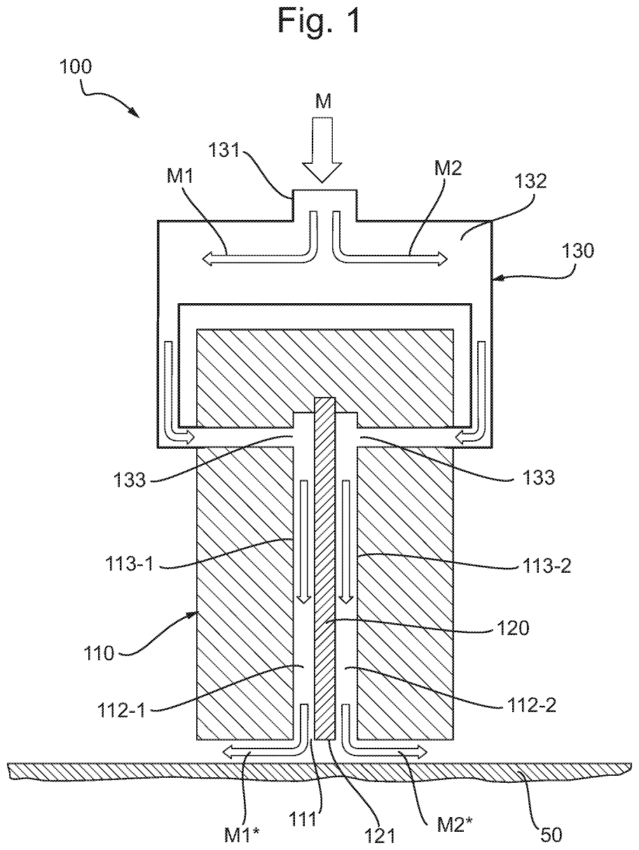

FIG. 1 illustrates a plasma source 100, comprising a plasma deposition head 110 with an aperture 111 for delivering an atmospheric plasma from the deposition head 110 to a substrate 50. The plasma deposition head can e.g. be made of an electrically conductive material, for example a metal, such as a steel or aluminium alloy. The plasma deposition head 110 comprises a slotted cavity 112 having parallel walls 113-1, 113-2, extending from opposing edges of the aperture 111. The plasma deposition head 110 can e.g. be manufactured as a single part wherein the slotted cavity 112 is e.g. formed by milling, EDM, or other suitable material removal processes. Alternatively, the plasma deposition head 110 can be composed of multiple sub-parts, which in assembled state, form the slotted cavity 112.

An electrode plate 120 is mounted in the slotted cavity 112 and extends from an interior of the deposition head 110 towards the aperture 111. The electrode plate 120 can for example comprise a metal electrode of which the sides are covered with a dielectric layer. For example, the electrode plate 120 may be a ceramic plate having a metal conductor buried inside, extending under the surface of the ceramic plate. Alternatively it may comprise laminated alumina layers, and the metal electrode may be printed on one of the alumina layers.

The plasma source 100 further comprises a gas supply system 130, comprising a gas inlet 131, a gas supply chamber 132 and gas outlets 133. The gas supply chamber 132 is arranged for receiving a mass flow of gas M from the gas inlet 131 and dividing the mass flow of gas between the gas outlets 133, e.g. into mass flows M1 and M2. As illustrated in FIG. 1, electrode plate 120 is mounted in the slotted cavity and extending from an interior of the deposition head towards the aperture in such way that gas outlets 133 are provided on opposing sides of the electrode plate 120, effectively creating two slots 112-1 and 112-2 which output plasma flows M1*, M2* respectively, after corresponding gas flows M1, M2 are guided along the opposing sides of plate 120. By mounting the electrode having both electrode surfaces freely suspended in the slotted cavity, a deviation from a planarity of one surface of the electrode plate in one direction towards one slotted wall 113, leading to an increased restriction along the electrode surface, and a corresponding reduction of plasma flow can be compensated on its opposed surface to the opposed slotted wall 113, which will have a corresponding decrease of a restriction, effectively compensating for each other, so that in the aperture 111, a reduction of plasma output in one slot 112-1 is compensated by a corresponding slot 112-2 opposed to the electrode plate.

As illustrated in FIG. 1, the electrode plate 120 comprises a distal edge 121 that may be aligned with the opposing edges of the aperture 111, such that mass flows of gas M1, M2 through the slotted cavity remain substantially separated by the electrode plate 120 until they exit the aperture 111. Preferably the alignment between the opposing edges of the aperture 111 and the distal edge 121 of the electrode plate 120 is within 3 millimeters, e.g. between 0 and 2 millimeters, more preferably between 0 and 1 millimeter.

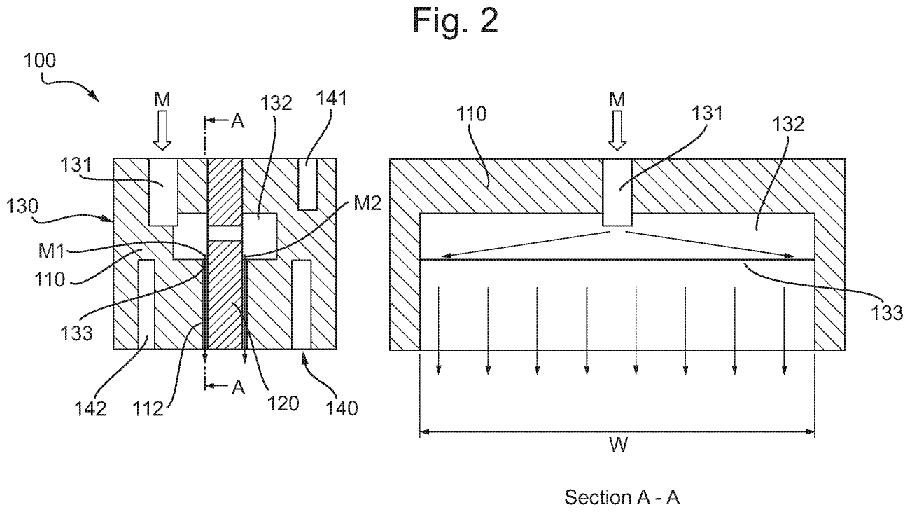

FIG. 2 illustrates an embodiment of the plasma source 100, wherein the gas supply system 130, e.g. the gas inlet 131, the gas supply chamber 132 and/or the gas outlets 133 are integrated in the plasma deposition head 110. These features can e.g. be provided by having holes, pockets, recesses or channels manufactured in the wall structure of the plasma deposition head 110. For example, the gas outlets 133 can be formed by an array of holes, or by a groove or slit extending into the wall of the slotted cavity 112. The array, groove or slit may be arranged along the width W of the electrode plate, to uniformly divide the mass flow of exhaust gas along the width of the electrode plate 120.

For similar reasons, as illustrated in FIG. 2, the gas supply chamber 132 may extend along a width W of the electrode plate 120 and across the opposing sides of the electrode plate 120. The electrode plate 120 may pass through the gas supply chamber 132, and one or more holes or cut outs may be provided in the electrode plate 120 inside the gas supply chamber 132 to allow passage of gas from one side of the electrode plate 120 to the other side.

The plasma deposition head 110 may further comprise an exhaust system 140 for discharging gas from the substrate. The exhaust system 140 for example comprises an exhaust port 141 and one or more exhaust channels 142 integrated in the plasma deposition head 110. As illustrated in FIG. 2, the exhaust channels 142 extend between the substrate and the exhaust port parallel to the slotted cavity 112.

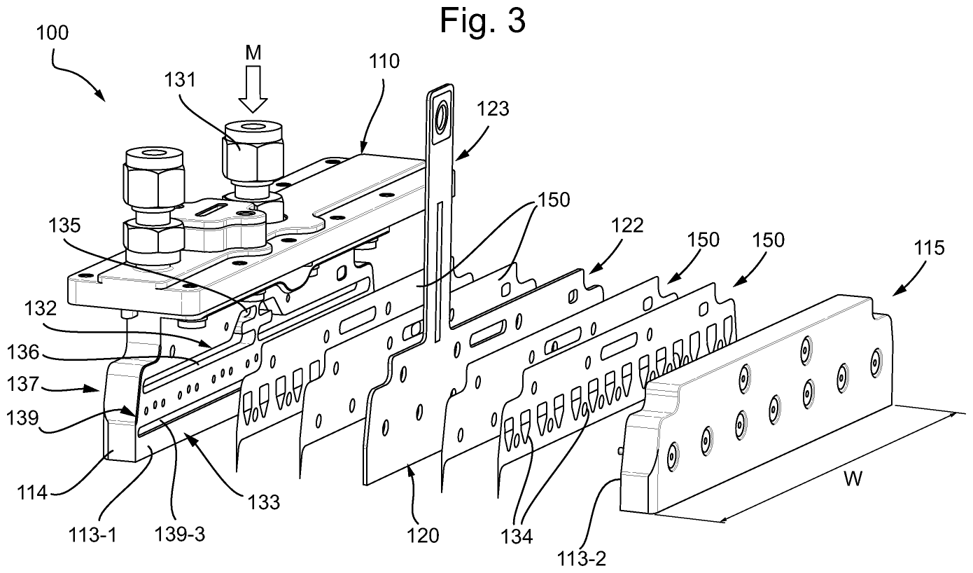

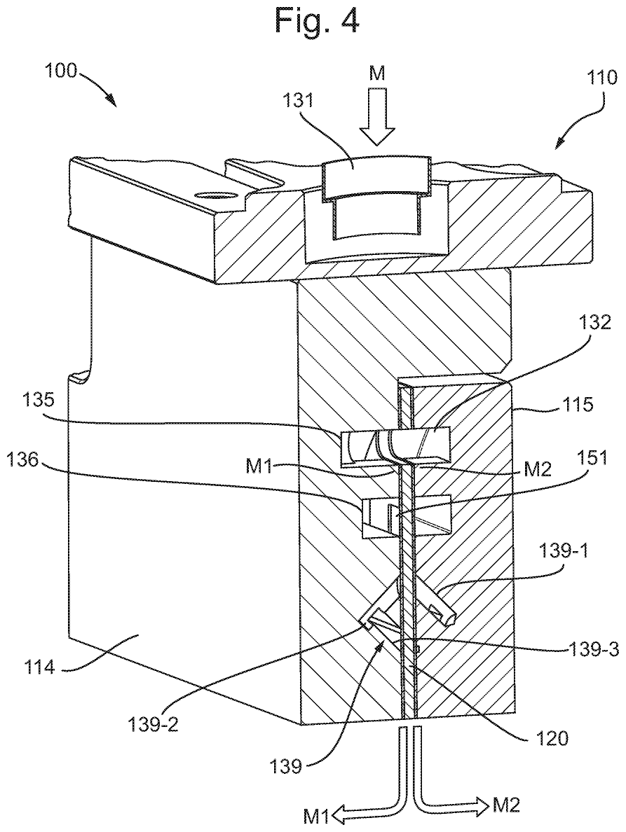

FIGS. 3 and 4 illustrate an exemplary embodiment of the plasma source 100, in which the plasma deposition head 110 comprises a first part 114 that defines a first wall 113-1 of the slotted cavity, and a second part 115 that defines a second wall 113-2 of the slotted cavity. The electrode plate 120 comprises a mountable part 122 that is mounted to the first and/or second part 114, 115 of the plasma deposition head. For example, the mountable part can be clamped between the first and second part 114, 115 of the plasma deposition head 110. The electrode plate 120 further comprises a suspendable part 123 that extends from the mountable part 122 and is free on all other sides.

On each opposing side of the electrode plate 120, a stack of shim plates 150 is clamped between the first or second part 114, 115 and the electrode plate 120. The stack of shim plates 150 can e.g. comprise two or more than two shim plates, wherein the shim plates have equal or different thicknesses. As shown in FIGS. 3 and 4, the stack of shim plates 150 covers the gas supply chamber 132 and the gas outlets 133, and each shim plate of the stack of shim plates is provided with cut outs 134, thereby creating a channel structure for directing the mass flow of gas from the gas supply chamber 132 through the stack of shim plates 150 towards the gas outlets 133.

The total thickness of each stack of shim plates 150 can be used to define a respective nominal gap width between the first and second walls 113-1, 113-2 of the slotted cavity and the opposing sides of the electrode plate 120. As such, by changing the number of shim plates, and/or by varying the thickness of the individual shim plates, the mass flow of gas along each opposing side of the electrode plate 120 can be determined.

As illustrated in FIGS. 3 and 4, functions of the gas supply system can be further separated by having the gas supply chamber 132 comprise a divide volume 135 and a supply volume 136. The divide volume 135 can be connected to the gas inlet 131 and may extend across the opposing sides of the electrode plate 120. Accordingly, the divide volume 135 is arranged for receiving the mass flow of gas M from the gas inlet 131, and for dividing the mass flow of gas M between the opposing sides of the electrode plate 120 into the divided mass flows of gas M1, M2.

The supply volume 136 can be connected to the divide volume 135 and may extend along the width W of the electrode plate 120. Accordingly, the supply volume 136 is arranged for receiving the divided mass flow of gas M1, M2 from the divide volume 135, and for uniformly supplying the divided mass flow of gas along the width W of the electrode plate 120 towards the gas outlets 133.

The divide volume 135 and the supply volume 136 may e.g. be formed by one or more recesses in the plasma deposition head 110. For example, as illustrated in FIG. 3, the divide volume 135 may comprise a first portion and a second portion, wherein the mass flow of gas is directed from the first portion in the first part 114 to a first portion in the second part 114, e.g. through a passage in the stacks of shims 150 and the electrode plate 120, then from the first portion in the second part 115 to a second portion in the second part 115, and next from the second portion in the second part 115 to a second portion in the first part 114, e.g. through another or the same passage in the stacks of shims 150 and the electrode plate 120. Accordingly, the mass flow of gas can be divided across the opposing sides of the electrode plate 120.

The supply volume 136, may for example comprise first and second branches that are connected to the first and second portions of the divide volume 135, respectively, as illustrated in FIG. 3. In this way, the mass flow of gas can be evenly distributed along the width W of the electrode plate 120.

The gas supply system 130 may further comprise a channelled section 137, e.g. comprising a plurality of channels 138 arranged along the width W of the electrode plate 120. The plurality of channels 138 can e.g. be arranged to connect the gas supply chamber 132 to respective gas outlets 133, wherein each channel of the plurality of channels 138 is arranged for directing a portion of the divided mass flow of gas M1, M2 from the gas supply chamber 132 towards a respective gas outlet 133.

As illustrated in FIGS. 3 and 4, the channelled section 137 can be provided by the stack of shim plates 150 described herein that are mounted between the slotted cavity walls 113-1, 113-2 and the electrode plate 120.

The channelled section 137 may comprise restrictions 151, arranged for increasing the flow resistance, to determine the divided mass flow of gas M1, M2 from the gas supply chamber 132 towards the gas outlets 133 along the width W of the electrode plate 120. The restrictions 151 can e.g. be formed by decreasing the size of one or more cut outs in the shim plates and/or by decreasing the thickness of one or more shim plates.

As illustrated in FIGS. 3 and 4, the gas supply system 130 may further comprise a flow homogenizer 139, disposed between the channelled section 137 and the gas outlets 133, and arranged for equally distributing a divided mass flow of gas M1, M2, along the width W of the electrode plate 120. The flow homogenizer 139 can e.g. comprise holes 139-1 that extend from the plurality of channels 138 into the wall 113-1, 113-2 at an acute angle and connect with a recess 139-2 in the wall 113-1, 113-2 that is in communication with the slotted cavity. The recess 139-2 may comprise a homogenizer plane 139-3 that is oriented substantially perpendicular to the divided mass flow of gas M1, M2, directed through the holes 139-1.

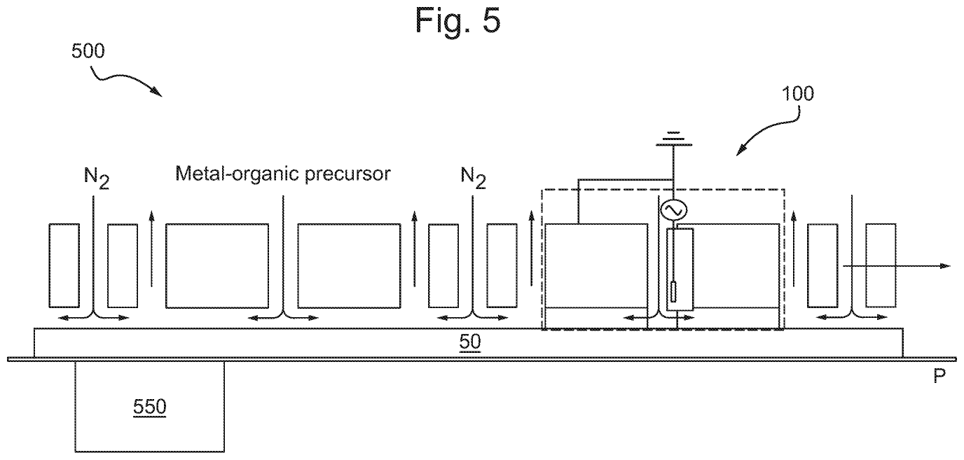

FIG. 5 represents an embodiment of an apparatus 500 for atomic layer deposition comprising a plasma source 100 as described herein. Besides the plasma source, the apparatus 500 may for example comprise a system for feeding agents and/or catalysts to the substrate, such as nitrogen or metal-organic precursors, and a system for discharging gases and materials from the substrate 50.

The apparatus 500 may further comprise a transport mechanism 550 arranged for transporting a substrate 50 and the plasma source 100 relative to each other in parallel to a plane P of the substrate 50. For example, the transport mechanism 550 can be arranged for transporting the substrate 50, e.g. along plane P, while the plasma source 100 is stationary. Alternatively, the substrate 50 may be held stationary while the transport mechanism 550 is arranged for transporting the plasma source 100 parallel to plane P.

It is thus believed that the operation and construction of the present invention will be apparent from the foregoing description and drawings appended thereto. For the purpose of clarity and a concise description features are described herein as part of the same or separate embodiments, however, it will be appreciated that the scope of the invention may include embodiments having combinations of all or some of the features described.

The invention applies not only to manufacturing applications where the plasma source is used for atomic layer deposition, but also to other technical, industrial or diagnostic applications where a plasma source is used. It will be clear to the skilled person that the invention is not limited to any embodiment herein described and that modifications are possible which may be considered within the scope of the appended claims. Also kinematic inversions are considered inherently disclosed and can be within the scope of the invention. In the claims, any reference signs shall not be construed as limiting the claim.

The term [symbol] aminated’ as used in the present application text and claims refers to the end result of any technique or process of manufacturing a material in multiple layers, so that the composite material achieves improved strength, stability, sound insulation, appearance, or other properties from the use of the differing materials. A laminated part, or laminate, is defined herein as a permanently assembled object, e.g. created using heat, pressure, electricity, welding, or adhesives. Various materials, techniques, and equipment may be used to provide a laminate. The present invention is not limited to electrode plates comprising laminated layers of alumina, but may comprise any other dielectric material suitable for use in a plasma source, such as glass, quartz, ceramics (e.g. alumina or zirconium dioxide), polymers, or combinations thereof. For example, a co-fired ceramic laminate may be manufactured by applying an electrode to a stack of layers, e.g. comprising layers that include a dielectric material, such as alumina or zirconium dioxide, and one or more layers that include an organic binder material, and thus heating the stack to form a composite.

The terms ‘comprising’ and ‘including’ when used in this description or the appended claims should not be construed in an exclusive or exhaustive sense but rather in an inclusive sense. Thus expression as ‘including’ or ‘comprising’ as used herein does not exclude the presence of other elements, additional structure or additional acts or steps in addition to those listed. Furthermore, the words ‘a’ and ‘an’ shall not be construed as limited to ‘only one’, but instead are used to mean ‘at least one’, and do not exclude a plurality. Features that are not specifically or explicitly described or claimed may additionally be included in the structure of the invention without departing from its scope.

Expressions such as: “means for . . . ” should be read as: “component configured for . . . ” or “member constructed to . . . ” and should be construed to include equivalents for the structures disclosed. The use of expressions like: “critical”, “preferred”, “especially preferred” etc. is not intended to limit the invention. To the extent that structure, material, or acts are considered to be essential they are inexpressively indicated as such. Additions, deletions, and modifications within the purview of the skilled person may generally be made without departing from the scope of the invention, as determined by the claims.

1. A plasma source, comprising:
a plasma deposition head comprising:
an aperture for delivering an atmospheric plasma from the plasma deposition head to a substrate; and
a slotted cavity having parallel walls extending from opposing edges of the aperture;
an electrode plate, mounted in the slotted cavity and extending from an interior of the plasma deposition head towards the aperture; and
a gas supply system comprising a gas inlet, a gas supply chamber, and plurality of gas outlets, wherein the gas supply chamber is arranged for receiving a mass flow of gas from the gas inlet and dividing the mass flow of gas between the plurality of gas outlets;
wherein the plurality of gas outlets are provided on opposing sides of the electrode plate, and wherein, in use, the mass flow of gas is divided for providing a flow of atmospheric plasma on the opposing sides of the electrode plate.

2. The plasma source according to claim 1, wherein the gas supply chamber extends along a width of the electrode plate and across the opposing sides of the electrode plate.

3. The plasma source according to claim 1, wherein the gas supply chamber and the plurality of gas outlets are integrated in the plasma deposition head.

4. The plasma source according to claim 3, wherein the gas supply chamber comprises:
a divide volume, connected to the gas inlet and extending across the opposing sides of the electrode plate, wherein the divide volume is arranged for receiving the mass flow of gas from the gas inlet, and dividing the mass flow of gas between the opposing sides of the electrode plate; and
a supply volume, connected to the divide volume and extending along a width of the electrode plate, wherein the supply volume is arranged for receiving the divided mass flow of gas from the divide volume, and uniformly supplying the mass flow of gas along the width of the electrode plate towards the plurality of gas outlets.

5. The plasma source according to claim 4, wherein the supply volume comprises a channelled section, wherein the channelled section comprises a plurality of channels arranged along the width of the electrode plate and connecting the gas supply chamber to respective gas outlets of the plurality of gas outlets, wherein each channel of the plurality of channels is arranged for directing a portion of the mass flow of gas from the gas supply chamber towards a respective gas outlet of the plurality of gas outlets.

6. The plasma source according to claim 5, wherein the channelled section is provided by a stack of shim plates, mounted between one of the parallel walls of the slotted cavity and the electrode plate, wherein the stack of shim plates covers the gas supply chamber and the plurality of gas outlets, wherein the plurality of channels is provided by cut outs in each shim plate of the stack of shim plates.

7. The plasma source according to claim 6, wherein the channelled section comprises restrictions for determining the mass flow of gas from the gas supply chamber towards the plurality of gas outlets along the width of the electrode plate.

8. The plasma source according to claim 7, wherein the restrictions are formed by decreasing a size of one or more cut outs in each shim plate of the stack of shim plates.

9. The plasma source according to claim 7, wherein the restrictions are formed by decreasing a thickness of one or more shim plates of the stack of shim plates.

10. The plasma source according to claim 5, wherein the gas supply system comprises a flow homogenizer arranged for equally distributing the mass flow of gas along the width of the electrode plate, wherein the flow homogenizer comprises holes that extend from the plurality of channels into a first wall of the parallel walls of the slotted cavity at an acute angle and connect with a recess in the first wall that is in communication with the slotted cavity, and wherein the recess comprises a homogenizer plane that is oriented substantially perpendicular to the mass flow of gas directed through the holes.

11. The plasma source according to claim 1, wherein the plasma deposition head further comprises:
a first part that defines a first wall of the parallel walls of the slotted cavity; and
a second part that defines a second wall of the parallel walls of the slotted cavity,
wherein the electrode plate comprises:
a mountable part that is mounted to at least one of the first part or the second part of the plasma deposition head; and
a suspendable part that extends from the mountable part and is free on all other sides.

12. The plasma source according to claim 11, wherein the mountable part is clamped between the first part and the second part of the plasma deposition head.

13. The plasma source according to claim 11, wherein on each opposing side of the electrode plate, a stack of shim plates is clamped between the first part or the second part and the electrode plate, wherein each stack of shim plates covers the gas supply chamber and the plurality of gas outlets, wherein each shim plate of each stack of shim plates is provided with cut outs, thereby creating a channel structure, for directing the mass flow of gas from the gas supply chamber through each stack of shim plates towards the plurality of gas outlets.

14. The plasma source according to claim 13, wherein each stack of shim plates has a total thickness that defines a respective nominal gap width between the first wall and the second wall of the slotted cavity and the opposing sides of the electrode plate.

15. The plasma source according to claim 1, wherein the plasma deposition head further comprises an exhaust system for discharging gas from the substrate, the exhaust system comprising an exhaust port and one or more exhaust channels integrated in the plasma deposition head, wherein the one or more exhaust channels extend between the substrate and the exhaust port parallel to the slotted cavity.

16. The plasma source according to claim 1, wherein the electrode plate comprises a distal edge that is aligned with the opposing edges of the aperture within 3 millimeters.

17. The plasma source according to claim 1, wherein the electrode plate comprises laminated alumina layers and wherein a metal electrode is printed on one of the alumina layers.

18. The plasma source according to claim 1, wherein the plasma deposition head is made of an electrically conductive material.

19. An apparatus for atomic layer deposition comprising the plasma source according to claim 1.

20. The apparatus according to claim 19, further comprising a transport mechanism arranged for transporting the substrate and the plasma source relative to each other in parallel to a plane of the substrate.
